(19) United States
(12) Patent Application Publication
(10) Pub. No.: US 2011/0037350 A1
(43) Pub. Date: Feb. 17, 2011

(54) PIEZOELECTRIC ACTUATOR MODULE HAVING CABLE BUSHINGS, AND METHOD FOR THE PRODUCTION THEREOF

(76) Inventors: Joerg Preibisch, Lichtenfels (DE); Stefan Leiser, Stuttgart (DE); Marco Stieber, Ditzingen (DE); Jens Leister, Kornwestheim (DE); Garoline Grube, Tamm (DE); Philipp Wachter, Bad Cannstatt (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/664,773

(22) PCT Filed: May 29, 2008
(86) PCT No.: PCT/EP2008/056574

§ 371 Date: Oct. 21, 2010

(30) Foreign Application Priority Data
Jun. 15, 2007 (DE) 10 2007 027 665.8

(51) Int. Cl. H01L 41/053; H01L 41/22

(52) U.S. Cl. 310/348; 29/25.35

(57) ABSTRACT

The invention relates to a piezoelectric actuator module having cable bushings for a piezoelectric actuator, and a piezoelectric actuator module produced in such a manner. Piezoelectric elements are disposed between an actuator head and an actuator base. Insulated extending conductors and feed cables are present in the ceramic actuator base for the electric contacting of the piezoelectric elements via exterior electrodes. During a sintering process for the ceramic actuator base, the electrically conductive inserts are sintered into the actuator base as conductors in an electrically insulating manner. The conductors are electrically connected to contact points on the piezoelectric elements having the exterior electrodes, and via further contact points to feed cables for the piezoelectric actuator module.

### PRIOR ART

The invention relates to a piezoelectric actuator module having cable bushings for a piezoelectric actuator, and to a method for its production, for the electrical contacting of the piezoelectric actuator in the piezoelectric actuator module, as generically defined by the preamble to the main claim.

One such piezoelectric actuator module may be used for instance as a piezoelectric injector for metering fuel in a precisely timed way and in a precise quantity in an internal combustion engine, and it essentially comprises a retaining body and the piezoelectric actuator, known per se, that is disposed in the retaining body and that has piezoelectric elements, stacked one above the other between an actuator head and an actuator base, which each comprise piezoelectric layers enclosed by inner electrodes. The piezoelectric elements for the piezoelectric layers are constructed, using a material that has a suitable crystalline structure (piezoelectric ceramic), in such a way that when an external voltage is applied to the inner electrodes, a mechanical reaction of the piezoelectric elements ensues, which depending on the crystalline structure and on the regions to which the electrical voltage is applied represents compression or tension in a predeterminable direction. The piezoelectric actuator in the case of a piezoelectric injector is connected to a nozzle needle, so that by application of an electrical voltage to the piezoelectric elements, a nozzle opening is uncovered or closed.

From German Patent Disclosure DE 101 39 871 A1, a piezoelectric injector of this kind, with a piezoelectric actuator module acting on a valve member via a hydraulic pressure booster, is known in which the piezoelectric elements of the piezoelectric actuator are disposed in a sleeve-and-diaphragm combination. On one end is a steel component (actuator base), through which the electrical contacting of the piezoelectric elements of the piezoelectric actuator is made possible via insulated lead lines.

What here is a necessary high-pressure-proof embedding of the electric lead lines into the piezoelectric actuator module, particularly into the actuator base, is described for instance in German Patent Disclosure 10 2004 004 706 A1. This reference proposes, among other things, embedding the cable of the lead line by means of a molten glass seal, for instance again in a ceramic component as the actuator base. In this known arrangement, the actuator base, as a ceramic component, is braced in the retaining body of a piezoelectric injector via frustoconical contact faces, at a mechanical initial tension.

In this case, care must be taken that molten-glass sealing, for instance against pressures of approximately 2000 bar, must be accomplished in the actuator base of the piezoelectric actuator module. The aforementioned molten glass seal is either pressed as a separate component into a supporting component of metal, or the glass is sealed directly into the metal part. This arrangement is disadvantageous, above all because it might not be possible to make the pressed connection completely tight, and making electrical contact might be very complicated.

### DISCLOSURE OF THE INVENTION

The invention is based on a piezoelectric actuator module as described at the outset with cable bushings for a piezoelectric actuator, which has piezoelectric elements disposed between an actuator head and an actuator base. Lines extending in insulated fashion are present in the ceramic actuator base for electrical contacting the piezoelectric elements via outer electrodes. According to the invention, electrically conductive inserts are advantageously jointly sintered into the ceramic actuator base as conductors in the actuator base and are connected to the outer electrodes at contact points to the piezoelectric elements and on the other end are connected via further contact points to the lead lines for the electrical triggering of the piezoelectric actuator module.

Moreover, with a frustoconical contact face, the ceramic actuator base can advantageously be joined sealingly to and braced on a corresponding contact face in a retaining body, and then the outer lead lines can be joined to the sintered-in conductive inserts. With appropriate mechanical initial tension on the piezoelectric actuator, the requisite sealing force for the cone, a force that is necessary to seal off the space containing the piezoelectric actuator from the outside, can then be exerted by the actuator base. The conductive inserts can be formed in a simple way by means of wires, which are capable of being joined to the outer electrodes and/or the lead lines via soldered or welded connections.

The introduction of the electrically conductive inserts can advantageously be effected during a sintering process for the actuator base and/or the piezoelectric actuator. After that, adhesive bonding to other components can be done.

In a preferred exemplary use, a piezoelectric actuator module with the aforementioned cable bushings is a component of a piezoelectric injector for an injection system for fuel in an internal combustion engine, in which the fuel to be injected is located in the same space as the piezoelectric actuator. The ceramic actuator and the piezoelectric actuator are joined together by gluing, for example.

### BRIEF DESCRIPTION OF THE DRAWINGS

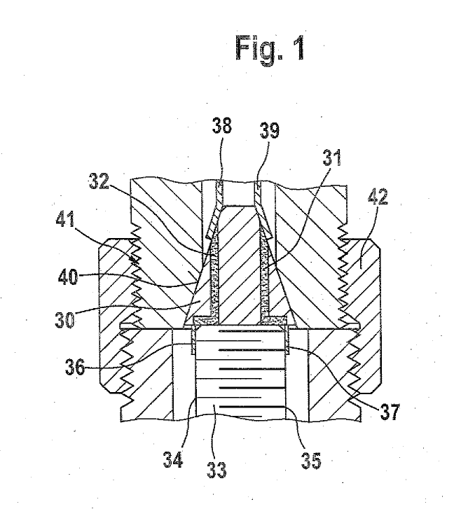

The invention will be described below in terms of an exemplary embodiment shown in the drawing in a single FIG. 1, which shows a separate view of the actuator base of the piezoelectric actuator module of the invention with sintered-in conductors in a ceramic actuator base, as cable bushings

### EMBODIMENT OF THE INVENTION

FIG. 1 shows regions essential to the invention of a piezoelectric actuator module, with an actuator base 30. A piezoelectric actuator module of this kind is already known from the prior art assessed in the introduction above, and as described there, it can be used for instance for needle stroke control in the injection system for fuel in an internal combustion engine.

In FIG. 1, cable bushings of the invention are shown in the actuator base 30; here they are inserted as sintered-in conductors 31 and 32. A piezoelectric actuator 33 is shown schematically here and is connected by its outer electrodes 34 and 35 to the conductors 31 and 32 by means of contact points 36 and 37, for instance by means of soldering.

Lead lines 38 and 39 are joined onto the other end of the conductors 31 and 32, and with the aid of these lead lines, the outer contacting of the piezoelectric actuator module of the invention can be accomplished. Via a frustoconical contact face 40, the actuator base 30 is sealingly and in self-boosting fashion pressed and braced against components of a retaining body 41, and two housing parts of the retaining body 41 are screwed together in a manner known per se here by means of a nut 42. It can thus be assured that a high mechanical initial tension acts on the piezoelectric actuator 33, since the necessary sealing force can easily be exerted via the frustoconical contact face 40.

1-5. (canceled)

6. A piezoelectric actuator module having cable bushings for a piezoelectric actuator, which module comprising:
piezoelectric elements disposed between an actuator head and an actuator base of a piezoelectric actuator;
lead lines extending in insulated fashion in the actuator base and which are in electrical contact with the piezoelectric elements via outer electrodes of the piezoelectric actuator; and
electrically conductive inserts being jointly sintered in electrically insulated fashion as conductors in the actuator base, thereby forming the cable bushings which are connected electrically to the outer electrodes to the piezoelectric elements via contact points and to the lead lines via further contact points, wherein the actuator base is ceramic.

7. The piezoelectric actuator module as defined by claim 6, wherein the actuator base, which has a frustoconical contact face, is sealingly joined to and braced on a corresponding contact face in a retaining body for the actuator base.

8. The piezoelectric actuator module as defined by claim 6, wherein the conductors are wires, which are joined via soldered or welded connections to the outer electrodes and/or to the lead lines.

9. The piezoelectric actuator module as defined by claim 7, wherein the conductors are wires, which are joined via soldered or welded connections to the outer electrodes and/or to the lead lines.

10. The piezoelectric actuator module as defined by claim 6, wherein the piezoelectric actuator module is produced with a cable bushing, and wherein the piezoelectric actuator module is a component of a piezoelectric injector for an injection system for fuel in an internal combustion engine.

11. The piezoelectric actuator module as defined by claim 7, wherein the piezoelectric actuator module is produced with a cable bushing, and wherein the piezoelectric actuator module is a component of a piezoelectric injector for an injection system for fuel in an internal combustion engine.

12. The piezoelectric actuator module as defined by claim 8, wherein the piezoelectric actuator module is produced with a cable bushing, and wherein the piezoelectric actuator module is a component of a piezoelectric injector for an injection system for fuel in an internal combustion engine.

13. The piezoelectric actuator module as defined by claim 9, wherein the piezoelectric actuator module is produced with a cable bushing, and wherein the piezoelectric actuator module is a component of a piezoelectric injector for an injection system for fuel in an internal combustion engine.

14. A method for producing a piezoelectric actuator module according to claim 6, the method comprising a sintering process for the actuator base and/or the piezoelectric actuator, during which process the conductive inserts are jointly sintered in place as conductors.

15. A method for producing a piezoelectric actuator module according to claim 7, the method comprising a sintering process for the actuator base and/or the piezoelectric actuator, during which process the conductive inserts are jointly sintered in place as conductors.

16. A method for producing a piezoelectric actuator module according to claim 8, the method comprising a sintering process for the actuator base and/or the piezoelectric actuator, during which process the conductive inserts are jointly sintered in place as conductors.

17. A method for producing a piezoelectric actuator module according to claim 9, the method comprising a sintering process for the actuator base and/or the piezoelectric actuator, during which process the conductive inserts are jointly sintered in place as conductors.

18. A method for producing a piezoelectric actuator module according to claim 10, the method comprising a sintering process for the actuator base and/or the piezoelectric actuator, during which process the conductive inserts are jointly sintered in place as conductors.

19. A method for producing a piezoelectric actuator module according to claim 11, the method comprising a sintering process for the actuator base and/or the piezoelectric actuator, during which process the conductive inserts are jointly sintered in place as conductors.

20. A method for producing a piezoelectric actuator module according to claim 12, the method comprising a sintering process for the actuator base and/or the piezoelectric actuator, during which process the conductive inserts are jointly sintered in place as conductors.

21. A method for producing a piezoelectric actuator module according to claim 13, the method comprising a sintering process for the actuator base and/or the piezoelectric actuator, during which process the conductive inserts are jointly sintered in place as conductors.
